(19) United States
(12) Patent Application Publication
(10) Pub. No.: US 2026/0293056 A1
(43) Pub. Date: Sep. 24, 2026

(54) HEAT DISSIPATION MODULE, HEAT DISSIPATION FIN, AND MANUFACTURING METHOD THEREOF FOR INCREASING HEAT CONTACT AREA

(71) Applicant: JWS TECHNOLOGY CO., LTD., New Taipei City (TW)

(72) Inventors: Pang-Hung LIAO, New Taipei City (TW); Shih-Ming WANG, New Taipei City (TW); Chih-Wei CHEN, New Taipei City (TW)

(21) Appl. No.: 19/086,485

(22) Filed: Mar. 21, 2025

(51) Int. Cl. H05K 7/20

(52) U.S. Cl. CPC H05K 7/20418; H05K 7/20463

(57) ABSTRACT

A heat dissipation module and its heat dissipation fin along with a manufacturing method for increasing a heat contact area are provided for use with a solder. The heat dissipation module includes a heat dissipation fin assembly and a heat pipe. The heat dissipation fin assembly includes heat dissipation fins spaced apart in parallel. A sheet body of each fin features a through-hole and one or more blind holes communicating with the through-hole. Each blind hole contains a continuous closed bottom wall, a semi-circular peripheral wall, and a communication port formed on one side of the semi-circular peripheral wall and communicating with the through-hole. The heat pipe is inserted through each through-hole. The solder may be placed in each blind hole and filled between the heat pipe and the inner periphery of each through-hole through each communication port, thereby enhancing the thermal conductivity of the heat dissipation module and fins.

### BACKGROUND OF THE DISCLOSURE

### Technical Field

The present disclosure relates to a heat dissipation structure comprising a heat pipe and fins, and in particular, to a heat dissipation module, a heat dissipation fin, and a manufacturing method thereof for increasing a heat contact area.

### Description of Related Art

To ensure that electronic components with high heat generation, such as central processing units (CPUs), memory modules, graphics processing units (GPUs), and chipsets, operate effectively within information systems, additional heat dissipation modules are employed. These modules are designed to remove excess heat from the components, thereby maintaining the temperature of actively operating electronic components within their safe operating limits.

A related-art heat dissipation module includes a plurality of heat dissipation fins and a heat pipe. Each heat dissipation fin is provided with a through-hole and a solder pass-through hole communicating with the through-hole. First, the heat dissipation fins are arranged at intervals, and the solder pass-through holes are positioned above the through-holes. Then, the heat pipe is inserted through the through-holes of each heat dissipation fin. Subsequently, a soldering pin is used to draw tin solder through the solder pass-through hole. The gravitational force and the capillary action created by a gap between the heat dissipation fins and the heat pipe allow the molten tin solder to flow downward, filling the contact interface between the heat pipe and the heat dissipation fins, thus completing the assembly process of the heat pipe with the multiple fins.

However, as the tin solder fills the contact interface between the heat pipe and the heat dissipation fin, tin solder loss at the solder pass-through hole results in the formation of a void area. This void area, containing only air and lacking a high thermal conductivity medium, impedes the thermal conduction between the heat pipe and the heat dissipation fin in the void area. Consequently, this reduces the effective heat contact area between the heat pipe and the fin, leading to diminished heat dissipation efficiency of the heat dissipation module.

In light of this, the inventor has deeply engaged in research and applied theoretical principles to address the shortcomings of the existing technologies. Addressing these issues has become the focal point of the inventor's development efforts.

### SUMMARY OF THE INVENTION

The present disclosure provides a heat dissipation module, a heat dissipation fin, and a manufacturing method thereof for increasing a heat contact area. The heat dissipation fin is provided with a blind hole communicating with a through-hole. A solder may be placed in the blind hole and filled between the heat pipe and an inner periphery of the through-hole through the blind hole, thereby preventing a reduction in the heat contact area between the heat pipe and the heat dissipation fin. This design ensures that the heat dissipation module and the heat dissipation fin exhibit excellent thermal conductivity.

In one of the embodiments, the present disclosure provides a heat dissipation module for increasing a heat contact area, suitable for use with a solder. The heat dissipation module includes: a heat dissipation fin assembly including a plurality of heat dissipation fins spaced apart and arranged in parallel, each of the heat dissipation fins including a sheet body, each of the sheet bodies being equipped on its front surface with a through-hole and at least one blind hole communicating with the through-hole, wherein each of the blind holes contains a continuous closed bottom wall, a semi-circular peripheral wall integrally formed on an inner periphery of the continuous closed bottom wall, and a communication port defined on one side of the semi-circular peripheral wall and communicating with the through-hole; and a heat pipe inserted through each of the through-holes, wherein the solder is placed in each of the blind holes and filled between the heat pipe and an inner periphery of each of the through-holes through each of the communication ports.

In one of the embodiments, the present disclosure provides a heat dissipation fin for increasing a heat contact area, for use with a solder, the heat dissipation fin including: a sheet body equipped on its front surface with a through-hole and at least one blind hole communicating with the through-hole, wherein the blind hole contains a continuous closed bottom wall, a semi-circular peripheral wall integrally formed on an inner periphery of the continuous closed bottom wall, and a communication port defined on one side of the semi-circular peripheral wall and communicating with the through-hole; wherein the solder is placed in the blind hole.

In one of the embodiments, the present disclosure provides a manufacturing method of a heat dissipation module for increasing a heat contact area, including following steps: A) providing a plurality of heat dissipation fins, wherein each of the heat dissipation fins is equipped on its front surface with a through-hole and at least one blind hole communicating with the through-hole; B) providing a heat pipe and a solder, repeatedly mounting each heat dissipation fin onto the heat pipe through the through-hole and placing the solder in the blind hole, so that the heat pipe is inserted through the heat dissipation fins spaced apart and arranged in parallel; C) arranging the heat dissipation fins so that each of the blind holes is disposed above a corresponding one of the through-holes; and D) performing a heat treatment on the solder to melt the solder into a molten state, causing the molten solder to flow from each of the blind holes to a space between the heat pipe and an inner periphery of each of the through-holes.

In light of the above, the inside of the blind hole is closed at one end, and the high thermal conductivity medium extends continuously to the inner periphery of the through-hole. Therefore, even when the solder at the blind hole is lost, the inside of the blind hole remains with a continuous surface without a hollow state. Furthermore, the solder is filled between the heat pipe and the inner periphery of the through-hole, and the outer periphery of the heat pipe is fully connected via the solder to both the inner periphery of the through-hole and the inside of the blind hole, avoiding a decrease in the heat contact area between the heat pipe and the heat dissipation fin. Thus, the heat dissipation module and the heat dissipation fin of the present disclosure have desirable thermal conductivity.

### BRIEF DESCRIPTION OF THE DRAWINGS

FIG. 1 is a flow chart of a manufacturing method of a heat dissipation module of the present disclosure.

FIG. 2 is a schematic perspective view of a heat dissipation fin to be mounted onto a heat pipe according to the present disclosure.

FIG. 3 is a schematic perspective view showing the heat dissipation fin after being mounted onto the heat pipe with a solder placed in a blind hole, according to the present disclosure.

FIG. 4 is a schematic cross-sectional view of the heat dissipation fin after being mounted onto the heat pipe with the solder placed in the blind hole, according to the present disclosure.

FIG. 5 is a schematic enlarged view of an area outlined by a dotted box in FIG. 4.

FIG. 6 is a partially enlarged cross-sectional view of the heat dissipation module of the present disclosure.

FIG. 7 is a schematic perspective view of the heat dissipation fin to be mounted on the heat pipe according to another embodiment of the present disclosure.

FIG. 8 is a partially enlarged cross-sectional view of the heat dissipation module according to another embodiment of the present disclosure.

FIG. 9 is a schematic perspective view of the heat dissipation fin to be mounted onto the heat pipe according to still another embodiment of the present disclosure.

FIG. 10 is a partially enlarged cross-sectional view of the heat dissipation module according to still another embodiment of the present disclosure.

FIG. 11 is a flow chart of the manufacturing method of the heat dissipation module according to another embodiment of the present disclosure.

FIG. 12 is a schematic perspective view of the heat dissipation fin to be mounted onto the heat pipe according to yet another embodiment of the present disclosure.

FIG. 13 is a partially enlarged cross-sectional view of the heat dissipation module according to yet another embodiment of the present disclosure.

### DETAILED DESCRIPTION

The detailed description and technical content of the present disclosure are explained below with reference to the accompanying drawings. However, these drawings are intended solely for illustration and should not be construed as limiting the scope of this disclosure.

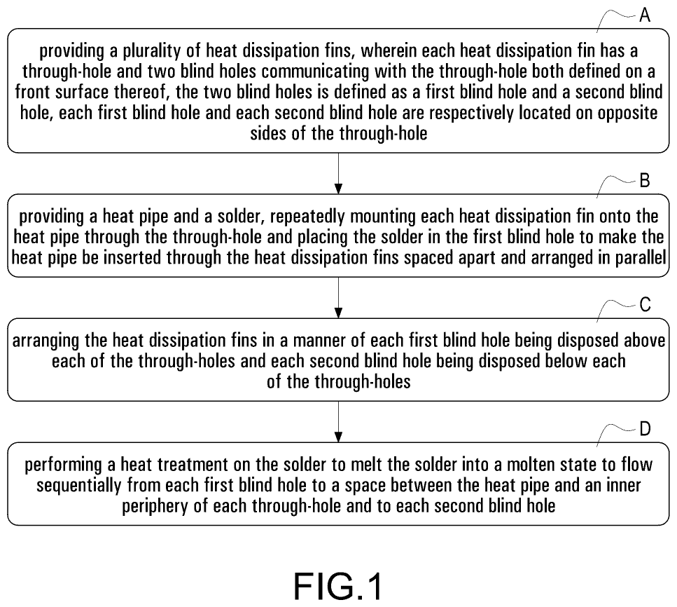

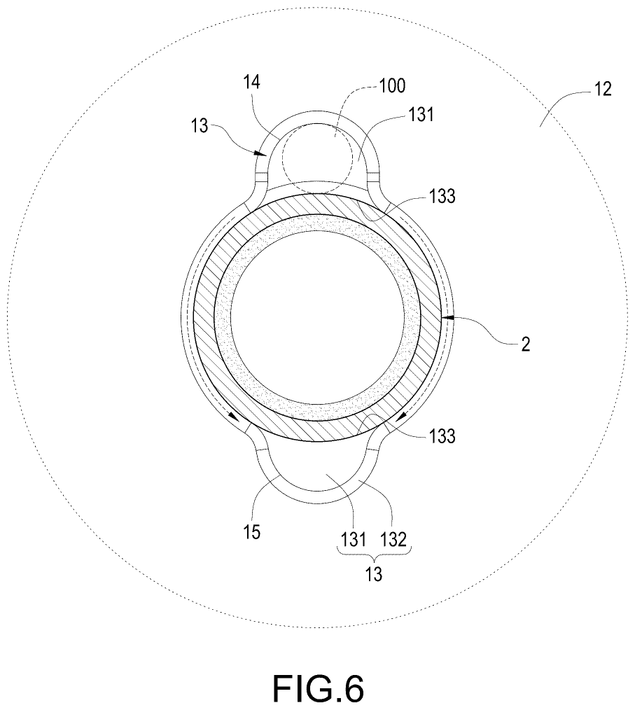

Please refer to FIGS. 1 to 6. The present disclosure provides a heat dissipation module, a heat dissipation fin, and a manufacturing method thereof for increasing a heat contact area, using with a solder 100, such as tin. The heat dissipation module 10 mainly includes a heat dissipation fin assembly 1 and a heat pipe 2. The heat dissipation fin 11 mainly includes a sheet body 12.

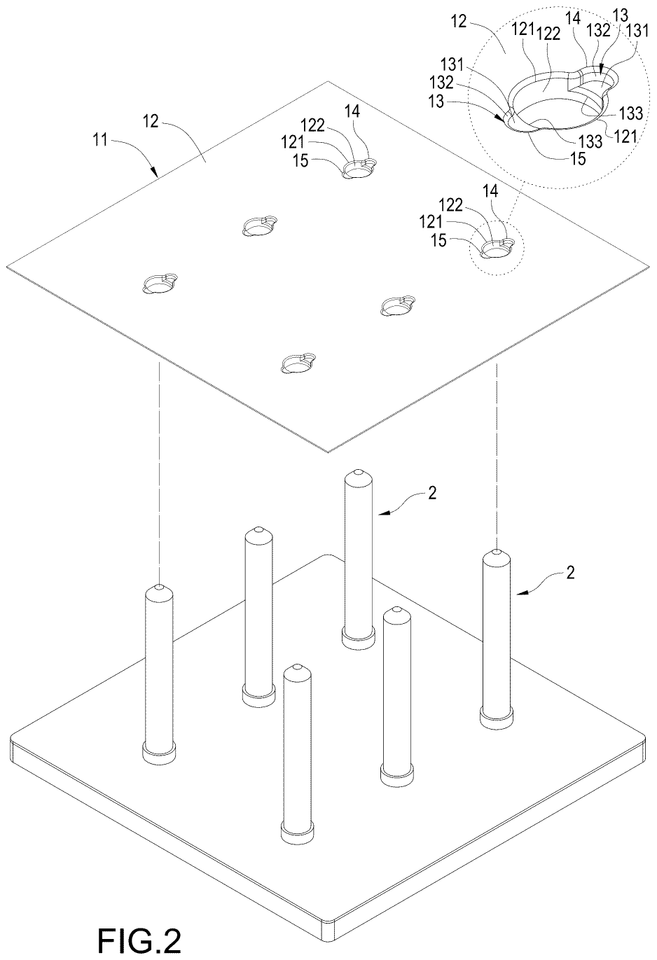

FIG. 1 shows steps of the manufacturing method of the heat dissipation module 10 according to one embodiment of the present disclosure. First, as outlined in step A of FIG. 1 and further depicted in FIG. 2, a plurality of heat dissipation fins 11 are provided, and a through-hole 121 and one or more blind holes 13 communicating with the through-hole 121 are provided on a front surface of each heat dissipation fin 11. In this embodiment, there are two blind holes 13, and the two blind holes 13 are designated as a first blind hole 14 and a second blind hole 15. In each heat dissipation fins 11, the first blind hole 14 and the second blind hole 15 are respectively located on opposite sides of the through-hole 121. A depth H1 of each first blind hole 14 is greater than or equal to a depth H2 of each second blind hole 15.

The details are as follows. Each heat dissipation fin 11 includes a sheet body 12. Each sheet body 12 is equipped on its front surface with a through-hole 121 and a first blind hole 14 and a second blind hole 15 communicating with the through-hole 121. These holes are created through stamping or other processing. The through-hole 121, the first blind hole 14, and the second blind hole 15 are arranged adjacent to each other. Each first blind hole 14 and each second blind hole 15 contain a continuous closed bottom wall 131, a semi-circular peripheral wall 132 that is integrally formed on an inner periphery of the continuous closed bottom wall 131, and a communication port 133. The communication port 133 is formed on one side of the semi-circular peripheral wall 132 and communicates to the through-hole 121.

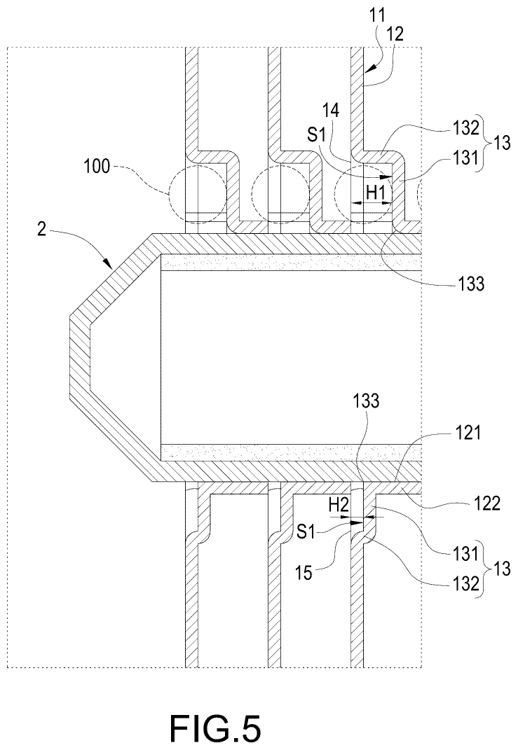

Further referring to FIG. 5, each sheet body 12 extends on its back surface with a ring 122 surrounding an inner periphery of each through-hole 121. A part of the inner periphery of each continuous closed bottom wall 131 is integrally formed with the semi-circular peripheral wall 132, and another part of the inner periphery of each continuous closed bottom wall 131 is integrally formed with the ring 122. Each communication port 133 is recessed from one end of each ring 122 connected to the front surface of each sheet body 12. In this embodiment, the surface of each continuous closed bottom wall 131 features a flat surface S1 that lies entirely on the same plane; however, the present application is not limited to this configuration.

Second, as shown in step B of FIG. 1 and FIGS. 2 to 3, one or more heat pipes 2 and a solder 100 are provided. The procedure involves repeatedly mounting each heat dissipation fin 11 onto the heat pipe 2 through the through-hole 121 and placing the solder 100 in the first blind hole 14. This ensures that the heat pipe 2 is inserted through the through-holes 121 of the heat dissipation fins 11 spaced apart and arranged side by side. These spaced and aligned heat dissipation fins 11 constitute the heat dissipation fin assembly 1. The heat pipe 2 may be inserted either tightly or with slight looseness into the through-hole 121.

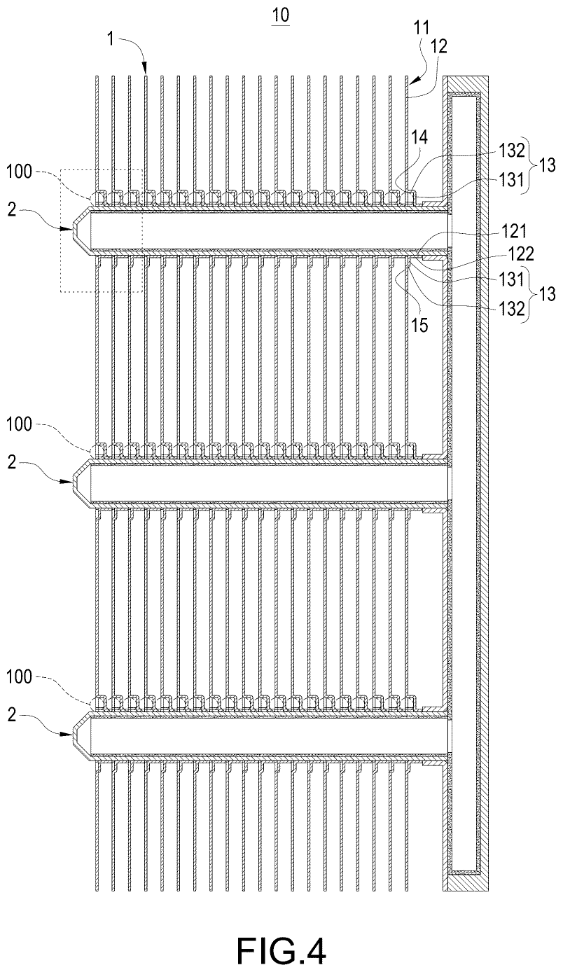

Third, as outlined in step C of FIG. 1 and depicted in FIGS. 4 to 5, the heat dissipation fins 11 are arranged such that each first blind hole 14 is positioned above a corresponding one of the through-holes 121, and each second blind hole 15 is positioned below a corresponding one of the through-holes 121.

Fourth, as outlined in step D of FIG. 1 and depicted in FIGS. 4 to 6, the solder 100 undergoes a heat treatment, melting the solder 100 into a molten state. This allows the molten solder 100 to flow sequentially from each first blind hole 14, filling the space between the heat pipe 2 and the inner periphery of each through-hole 121, and continuing to each second blind hole 15.

Finally, after the solder 100 cools, it fills between the heat pipe 2 and the inner periphery of each through-hole 121, and the overflowing solder 100 converges to the second blind hole 15, so that the solder 100 may be placed in each first blind hole 14 and filled between the heat pipe 2 and the inner periphery of each through-hole 121 through the communication port 133 of each first blind hole 14, and overflow to each second blind hole 15 through the communication port 133 of each second blind hole 15.

In related art, after the solder at a solder pass-through hole has filled between the heat pipe and the inner periphery of each through-hole, the loss of solder results in the formation of a hollow area at the solder pass-through hole. This hollow area interrupts the heat conduction between the heat pipe and the heat dissipation fin.

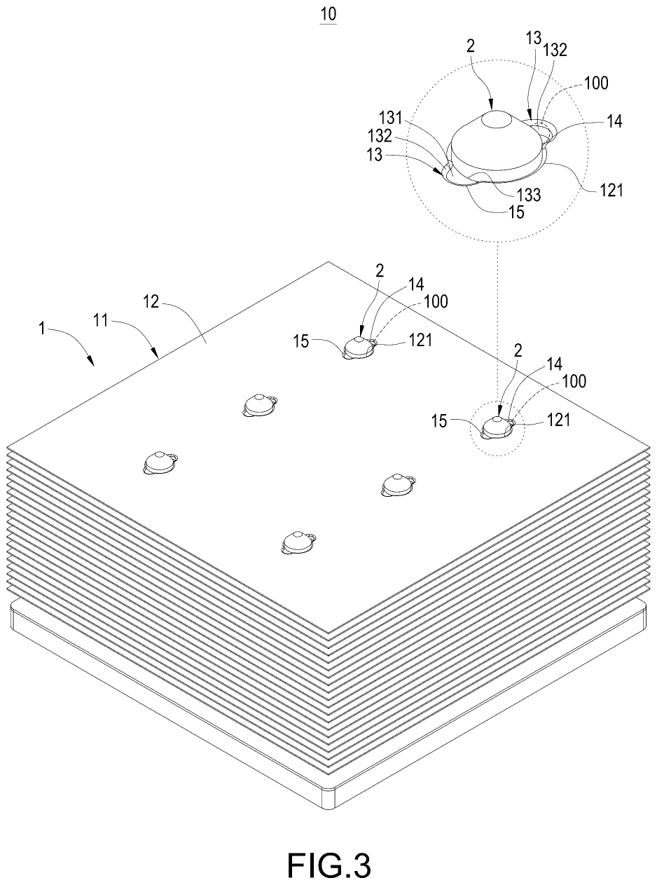

In contrast, as shown in FIGS. 3 to 6, the inside of the first blind hole 14 of the present disclosure is closed at one end, and a high thermal conductivity medium extends continuously to the inner periphery of the through-hole 121. Therefore, even when the solder 100 at the first blind hole 14 is lost, the inside of the first blind hole 14 remains with a continuous surface and without any hollow areas. Furthermore, the solder 100 is filled between the heat pipe 2 and the inner periphery of the through-hole 121, and the outer periphery of the heat pipe 2 is fully connected via the solder 100 to both the inner periphery of the through-hole 121 and the inside of the first blind hole 14, avoiding a decrease in the heat contact area between the heat pipe 2 and the heat dissipation fin 11. Thus, the heat dissipation module 10 and the heat dissipation fin 11 of the present disclosure have desirable thermal conductivity.

In addition, the overflowing solder 100 may be guided and concentrated into the second blind hole 15, allowing the solder 100 to fill more uniformly between the heat pipe 2 and the inner periphery of each through-hole 121. This helps prevent excessive solder 100 from spilling over the periphery of the through-hole 121 and forming solder beads around it after cooling. The solder beads increase thermal resistance and have a risk of falling off. If the solder beads fall on a circuit board (not illustrated in figures), they may cause a short circuit of the circuit board.

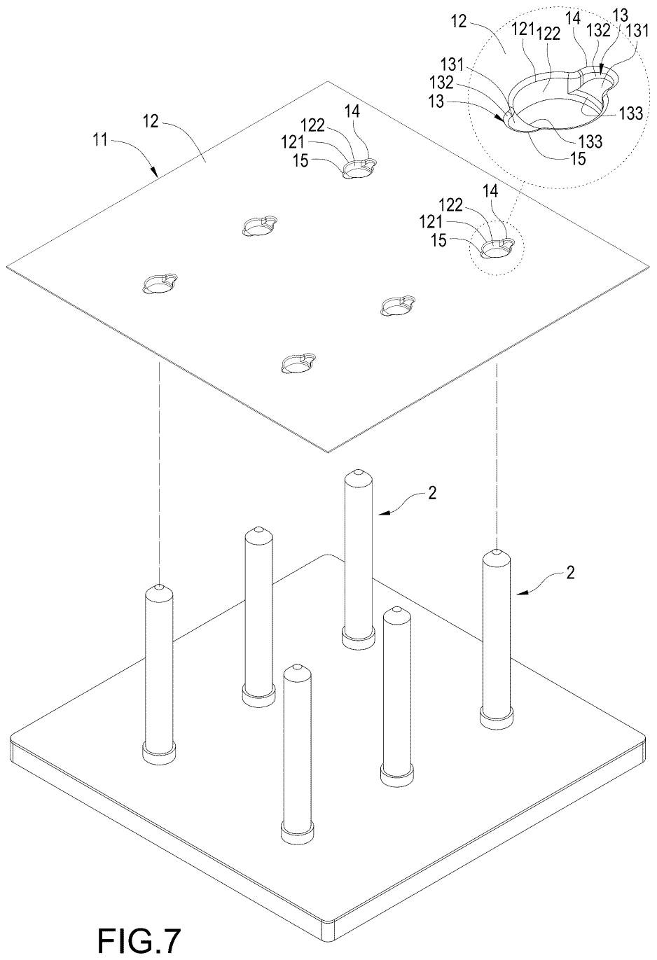

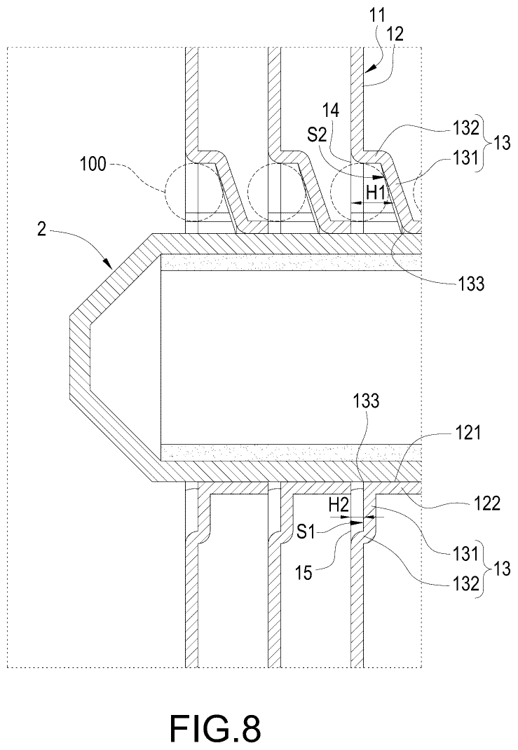

As shown in FIGS. 7 to 8, another embodiment of the heat dissipation module 10 and the heat dissipation fin 11 of the present disclosure is provided. The embodiment of FIGS. 7 to 8 is substantially the same as the embodiment of FIGS. 1 to 6, except that the surface of the continuous closed bottom wall 131 of each first blind hole 14 features a downwardly inclined surface S2 gradually and downwardly inclined toward the communication port 133. However, the present disclosure is not limited to this configuration.

Furthermore, the downwardly inclined surface S2, which slopes towards the communication port 133, may moderate the flow of molten solder 100 towards the space between the heat pipe 2 and the inner periphery of each through-hole 121. This design not only achieves the same functions and effects as the embodiment depicted in FIGS. 1 to 6 but also reduces the risk of overflow by diminishing the gravitational force component acting on the solder 100, thereby decreasing its fluidity.

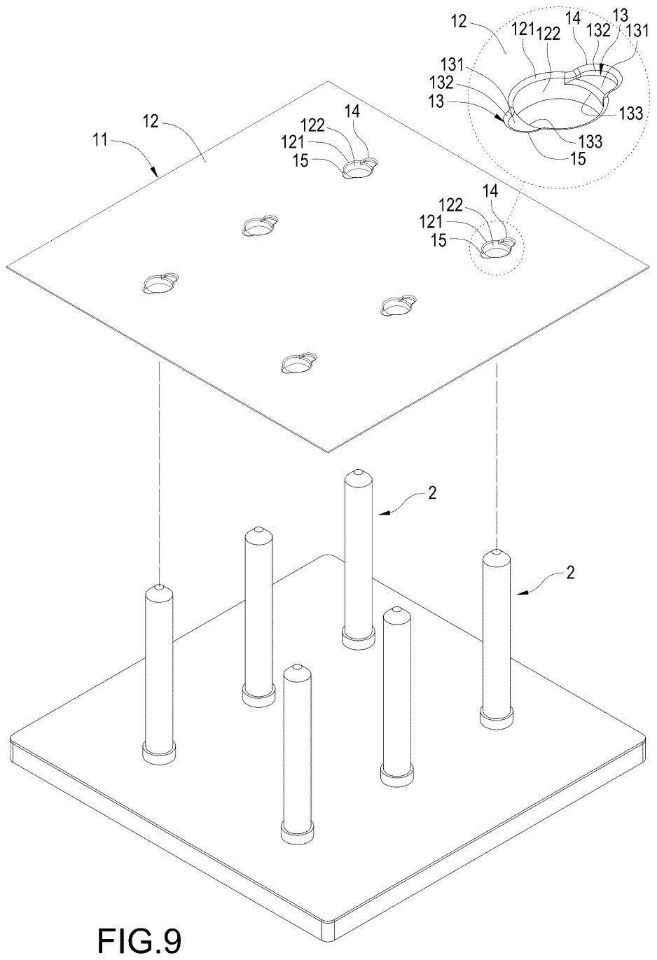

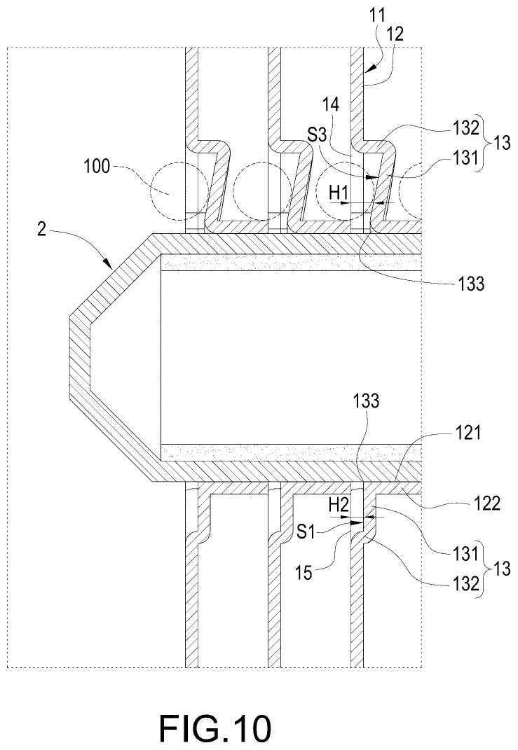

As shown in FIGS. 9 to 10, still another embodiment of the heat dissipation module 10 and the heat dissipation fin 11 of the present disclosure is provided. The embodiment of FIGS. 9 to 10 is substantially the same as the embodiment of FIGS. 1 to 6, except that the surface of the continuous closed bottom wall 131 of each first blind hole 14 features an upwardly inclined surface S3 gradually and upwardly inclined toward the communication port 133. However, the present disclosure is not limited to this configuration.

Furthermore, the upwardly inclined surface S3, which gradually slopes towards the communication port 133, accelerates the flow of the molten solder 100 into the space between the heat pipe 2 and the inner periphery of each through-hole 121. This configuration achieves the same functions and effects as the embodiments shown in FIGS. 1 to 6. Additionally, in this embodiment, an inner peripheral area of the ring 122 is larger than an inner peripheral area of the ring 122 in the embodiment of FIGS. 1 to 6 and an inner peripheral area of the ring 122 in the embodiment of FIGS. 7 to 8, which increases the contact area between the heat dissipation fin 11 and the heat pipe 2, thereby enhancing the heat exchange efficiency of the heat dissipation module 10 and the heat dissipation fin 11.

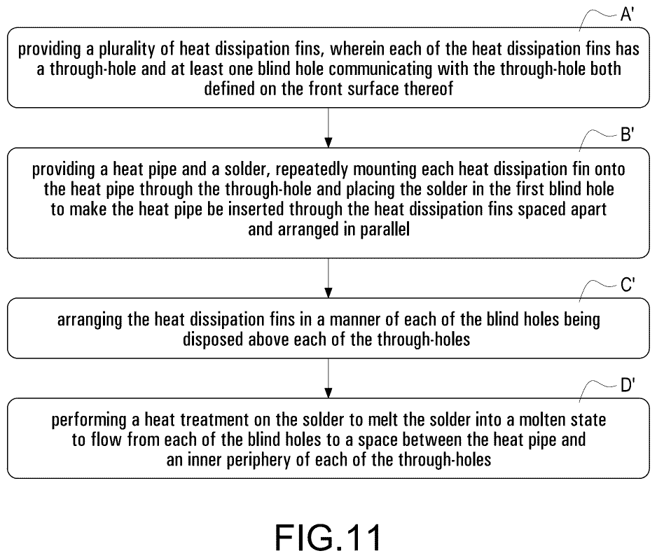

FIGS. 11 to 13 show steps of the manufacturing method of the present disclosure according to one embodiment and depict the heat dissipation module 10 and the heat dissipation fin 11 in yet another embodiment. The embodiment of FIGS. 11 to 13 is substantially the same as the embodiment of FIGS. 1 to 6, except that there is only one blind hole 13 in the current embodiment.

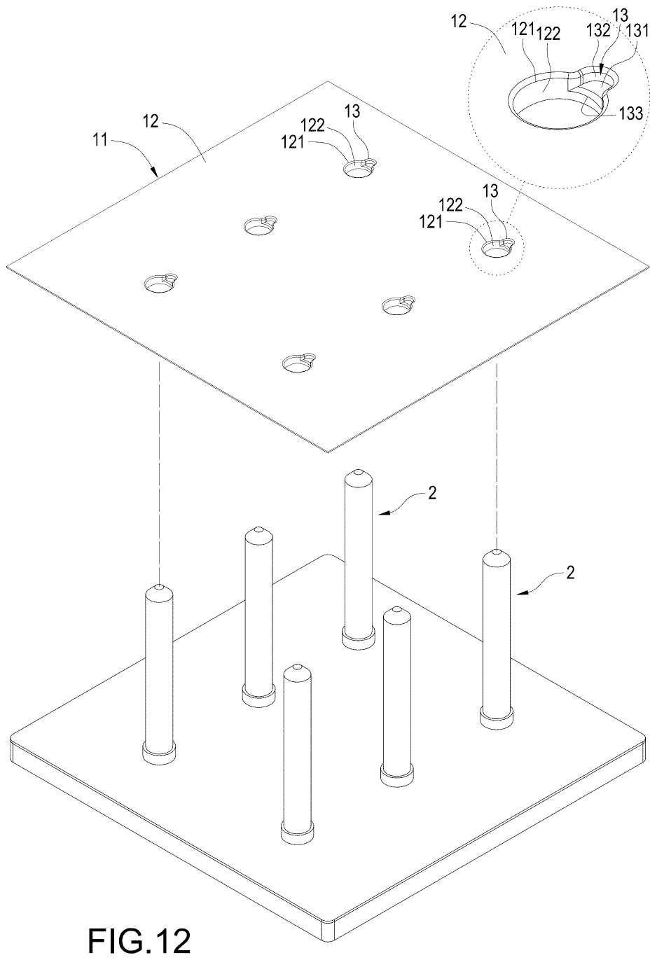

As shown in FIG. 11, this depicts steps of the manufacturing method of the heat dissipation module 10 according to one embodiment of the present disclosure. First, as shown in step A′ of FIG. 1 and FIG. 12, a plurality of heat dissipation fins 11 are provided, and a through-hole 121 and one blind hole 13 communicating with the through-hole 121 are positioned on a front surface of each heat dissipation fin 11.

The details are as follows. Each heat dissipation fin 11 includes a sheet body 12, and each sheet body 12 is provided on its front surface with a through-hole 121 and one blind hole 13 communicating with the through-hole 121 through stamping or other processing. Each through-hole 121 and its corresponding blind hole 13 are positioned adjacent to each other. Each blind hole 13 includes a continuous closed bottom wall 131, a semi-circular peripheral wall 132 integrally formed on the inner periphery of the continuous closed bottom wall 131, and a communication port 133 formed on one side of the semi-circular peripheral wall 132 and connected to the through-hole 121.

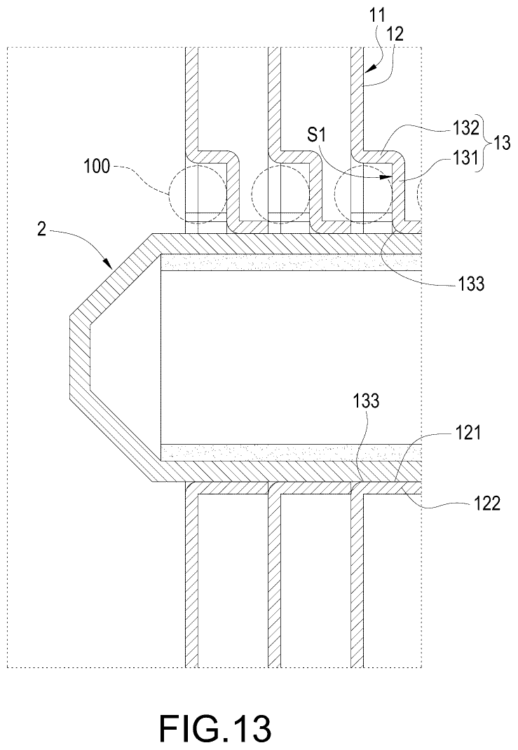

Further referring to FIG. 13, each sheet body 12 extends on its back surface with a ring 122 surrounding the inner periphery of each through-hole 121. A part of the inner periphery of each continuous closed bottom wall 131 is integrally formed with the semi-circular peripheral wall 132, and another part is integrally formed with the ring 122. Each communication port 133 is recessed from one end of each ring 122 connected to the front surface of each sheet body 12. In this embodiment, the surface of each continuous closed bottom wall 131 features a flat surface S1 that lies entirely on the same plane; however, the present application is not limited to this configuration.

Second, as shown in step B′ of FIG. 11 and FIGS. 12 to 13, one or more heat pipes 2 and a solder 100 are provided. The process involves repeatedly mounting each heat dissipation fin 11 onto the heat pipe 2 through the through-hole 121 and inserting the solder 100 into the blind hole 13. This ensures that the heat pipe 2 is inserted through the through-holes 121 of the heat dissipation fins 11 spaced apart and arranged in parallel, and the plurality of heat dissipation fins 11 spaced apart and arranged side by side. These spaced and aligned heat dissipation fins 11 constitute the heat dissipation fin assembly 1. The heat pipe 2 may be tightly inserted through the through-hole 121, or may be slightly loosely inserted through the through-hole 121.

Third, as shown in step C′ of FIG. 11 and FIG. 13, the heat dissipation fins 11 are positioned with each blind hole 13 disposed above a corresponding one of the through-holes 121.

Fourth, as shown in step D′ of FIG. 11 and FIG. 13, the solder 100 undergoes a heat treatment, melting the solder 100 into a molten state. This allows the molten solder 100 to flow from each blind hole 13 to the space between the heat pipe 2 and the inner periphery of each through-hole 121.

Finally, after the solder 100 cools, it fills between the heat pipe 2 and the inner periphery of each through-hole 121, so that the solder 100 may be placed in each blind hole 13 and filled between the heat pipe 2 and the inner periphery of each through-hole 121 through each communication port 133.

Therefore, as shown in FIGS. 3 to 6, since the inside of the blind hole 13 of the present disclosure is closed at one end, and a high thermal conductivity medium extends continuously to the inner periphery of the through-hole 121. Therefore, even when the solder 100 at the blind hole 13 is lost, the inside of the blind hole 13 remains with a continuous surface and without any hollow areas. Furthermore, the solder 100 is filled between the heat pipe 2 and the inner periphery of the through-hole 121, and the outer periphery of the heat pipe 2 is fully connected via the solder 100 to both the inner periphery of the through-hole 121 and the inside of the blind hole 13, avoiding a decrease in the heat contact area between the heat pipe 2 and the heat dissipation fin 11. Thus, the heat dissipation module 10 and the heat dissipation fin 11 of the present disclosure have excellent thermal conductivity.

In addition, in this embodiment, there is only one blind hole 13. Compared with the previous embodiments, there is no blind hole below the heat pipe 2 in this embodiment. However, by controlling the furnace temperature, the amount of solder, and the duration of the temperature holding time, it is possible to reduce the risk of overflow of the solder 100 without a blind hole below the heat pipe 2, and to avoid the loss of contact area of the heat dissipation fin 11 due to the blind hole, thereby improving the heat exchange efficiency of the heat dissipation module 10 and the heat dissipation fin 11.

What is claimed is:

1. A heat dissipation module for increasing a heat contact area, using with a solder, the heat dissipation module comprising:
a heat dissipation fin assembly, comprising a plurality of heat dissipation fins disposed spacedly and parallelly, each of the heat dissipation fins comprising a sheet body, the sheet body comprising a through-hole and at least one blind hole communicating with the through-hole both defined on a front surface thereof, wherein a continuous closed bottom wall, a semi-circular peripheral wall integrally formed on an inner periphery of the continuous closed bottom wall, and a communication port defined on one side of the semi-circular peripheral wall and communicating with the through-hole are all located in the blind hole; and
a heat pipe, inserted through the through-hole,
wherein the solder is placed in the blind hole and filled between the heat pipe and an inner periphery of the through-hole through the communication port.

2. The heat dissipation module as claimed in claim 1, wherein each of the heat dissipation fins comprises two blind holes, the two blind holes are defined as a first blind hole and a second blind hole, the first blind hole is positioned above the through-hole, the second blind hole is positioned below the through-hole, and a depth of the first blind hole is greater than or equal to a depth of the second blind hole, wherein the solder is placed in the first blind hole and filled between the heat pipe and the inner periphery of the through-hole through the communication port of the first blind hole, and overflows to the second blind hole through the communication port of the second blind hole.

3. The heat dissipation module as claimed in claim 1, wherein a surface of the continuous closed bottom wall is a flat surface disposed coplanarly.

4. The heat dissipation module as claimed in claim 1, wherein a surface of the continuous closed bottom wall is structured with a downwardly inclined surface gradually and downwardly inclined toward the communication port or an upwardly inclined surface gradually and upwardly inclined toward the communication port.

5. The heat dissipation module as claimed in claim 1, wherein the sheet body comprises a ring disposed on a back surface thereof and surrounding the inner periphery of the through-hole, one part of the inner periphery of the continuous closed bottom wall is integrally formed with the semi-circular peripheral wall and another part of the inner periphery of the continuous closed bottom wall is integrally formed with the ring, and the communication port is recessed from one end of the ring connected to the front surface of the sheet body.

6. A heat dissipation fin for increasing a heat contact area, using with a solder, the heat dissipation fin comprising:
a sheet body, comprising a through-hole and at least one blind hole communicating with the through-hole both defined on a front surface thereof, wherein a continuous closed bottom wall, a semi-circular peripheral wall integrally formed on an inner periphery of the continuous closed bottom wall, and a communication port defined on one side of the semi-circular peripheral wall and communicating with the through-hole are all located in the blind hole;
wherein the solder is placed in the blind hole.

7. The heat dissipation fin as claimed in claim 6, wherein the heat dissipation fin comprises two blind holes, the two blind holes are defined as a first blind hole and a second blind hole, the first blind hole is positioned above the second blind hole, and a depth of the first blind hole is greater than or equal to a depth of the second blind hole.

8. The heat dissipation fin as claimed in claim 6, wherein a surface of the continuous closed bottom wall is a flat surface disposed coplanarly.

9. The heat dissipation fin as claimed in claim 6, wherein a surface of the continuous closed bottom wall is structured with a downwardly inclined surface gradually and downwardly inclined toward the communication port or an upwardly inclined surface gradually and upwardly inclined toward the communication port.

10. The heat dissipation fin as claimed in claim 6, wherein the sheet body comprises a ring disposed on a back surface thereof and surrounding the inner periphery of the through-hole, one part of the inner periphery of the continuous closed bottom wall is integrally formed with the semi-circular peripheral wall and another part of the inner periphery of the continuous closed bottom wall is integrally formed with the ring, and the communication port is recessed from one end of the ring connected to the front surface of the sheet body.

11. A manufacturing method of a heat dissipation module for increasing a heat contact area, the manufacturing method comprising following steps:
A) providing a plurality of heat dissipation fins, wherein each of the heat dissipation fins comprises a through-hole and at least one blind hole communicating with the through-hole both defined on a front surface thereof;
B) providing a heat pipe and a solder, repeatedly mounting each heat dissipation fin onto the heat pipe through the through-hole and placing the solder in the blind hole to make the heat pipe be inserted through the heat dissipation fins spacedly and parallelly;
C) arranging the heat dissipation fins in a manner of the blind hole being disposed above the through-hole; and
D) performing a heat treatment on the solder to melt the solder into a molten state to flow from the blind hole to a space between the heat pipe and an inner periphery of the through-hole.

12. The manufacturing method as claimed in claim 11, wherein in the A), each of the heat dissipation fins comprises two blind holes defined as a first blind hole and a second blind hole, the first blind hole and the second blind hole of each heat dissipation fin are respectively located on two sides of the through-hole opposite to each other; in the B), the solder is placed in the first blind hole; in the C), the heat dissipation fins are arranged in a manner of the first blind holes being disposed above the through-hole and the second blind hole being disposed below the through-hole; in the D), the solder is melted and flows sequentially from the first blind hole into the space between the heat pipe and the inner periphery of the through-hole and the second blind hole.
